(19) United States
(12) Patent Application Publication
(10) Pub. No.: US 2026/0244300 A1
(43) Pub. Date: Aug. 20, 2026

(54) Floating button trigger induction adjustment system and method

(71) Applicant: DARWIN PRECISIONS CORPORATION, Hsinchu County (TW)

(72) Inventors: Chih-hung Liu, Hsinchu County (TW); YA HAN KO, Hsinchu County (TW); YU TENG LIN, Hsinchu County (TW); YAN-MIN LIOU, Hsinchu County (TW)

(21) Appl. No.: 19/537,588

(22) Filed: Feb. 12, 2026

(30) Foreign Application Priority Data
Feb. 14, 2025 (TW) 114105573

(51) Int. Cl. G06F 3/042

(52) U.S. Cl. CPC G06F 3/0421; G06F 2203/04109

(57) ABSTRACT

A floating button trigger induction adjustment system and method are provided, wherein the system includes a computer, a programming module, a test module, and a floating button circuit. The floating button circuit is installed on the test module to sense an object at a preset distance. The method includes that the computer writes a first program code into the floating button circuit through the programming module; the floating button circuit automatically adjusts a first current value of an infrared diode in the floating button circuit to emit infrared rays to the object until the floating button circuit obtains a reflected feedback signal associated with the infrared rays; the computer receives a second current value of the infrared diode associated with the reflected feedback signal from the floating button circuit; the computer writes a second program code including the second current value into the floating button circuit through the programming module.

### CROSS-REFERENCE TO RELATED PATENT APPLICATION

This application claims priority to Taiwan Patent Application No. 114105573, filed on Feb. 14, 2025. The entire contents of Taiwan Patent Application No. 114105573 are incorporated herein by reference.

### FIELD OF THE INVENTION

The present invention relates to a floating button trigger induction adjustment technology, and in particular to a floating button trigger induction adjustment system and method.

### BACKGROUND OF THE INVENTION

During production of a floating button, the operator, by using a computer in combination with a programming module, writes a program into a floating button circuit, installs the floating button circuit in a test module for measuring the sensing distance, and adjusts a distance between the floating button in the floating button circuit and an object on the test module, such as a white reflector plate. Next, the operator adjusts a variable resistance value in the floating button circuit so as to set the sensing distance of the floating button when the outer frame light of the floating button flashes out after the floating button is sensed. However, different floating button circuits will have different sensing distances for each floating button due to the differences in sensing components and optical modules, so the operator must adjust the variable resistance value of each floating button circuit to achieve the same sensing distance of each button. However, it is required to make adjustments repeatedly to confirm an accurate critical point of sensing, so it takes a long time for adjustments.

### SUMMARY OF THE INVENTION

The present invention provides a floating button trigger induction adjustment system and method which can shorten the time of adjusting the sensing distance of the floating button.

In order to achieve one or all of the above objectives or other objectives, an embodiment of the present invention provides a floating button trigger induction adjustment method, applicable to a floating button trigger induction adjustment system including a computer, a programming module, a test module, and a floating button circuit. The programming module is coupled to the computer. The floating button circuit is coupled to the computer and the programming module. The floating button circuit is installed on the test module to sense an object at a preset distance. The floating button trigger induction adjustment method includes: writing, by the computer, a first program code into the floating button circuit through the programming module; automatically adjusting, by the floating button circuit, a first current value of an infrared diode in the floating button circuit to emit infrared rays to the object until the floating button circuit obtains a reflected feedback signal associated with the infrared rays; receiving, by the computer, a second current value of the infrared diode associated with the reflected feedback signal from the floating button circuit; and writing, by the computer, a second program code including the second current value into the floating button circuit through the programming module.

In order to achieve one or all of the above objectives or other objectives, an embodiment of the present invention provides a floating button trigger induction adjustment system, including: a computer; a programming module, coupled to the computer; a test module; and a floating button circuit, coupled to the computer and the programming module, and installed on the test module to sense an object at a preset distance. A floating button trigger induction adjustment method is executed by the floating button trigger induction adjustment system to include: writing, by the computer, a first program code into the floating button circuit through the programming module; automatically adjusting, by the floating button circuit, a first current value of an infrared diode in the floating button circuit to emit infrared rays to the object until the floating button circuit obtains a reflected feedback signal associated with the infrared rays; receiving, by the computer, a second current value of the infrared diode associated with the reflected feedback signal from the floating button circuit; and writing, by the computer, a second program code including the second current value into the floating button circuit through the programming module.

In an embodiment of the present invention, the floating button trigger induction adjustment system further includes a motherboard control circuit coupled to the computer and the floating button circuit, and the floating button trigger induction adjustment method further includes: testing, by the computer, an anti-false touch function of the floating button circuit through the motherboard control circuit.

In an embodiment of the present invention, the computer automatically compiles the second program code to include the second current value.

In an embodiment of the present invention, the preset distance is 40mm.

In an embodiment of the present invention, the floating button circuit automatically adjusts the first current value of the infrared diode in the floating button circuit by pulse width modulation.

In the present invention, a programming program is adopted to automatically adjust the current value of the infrared diode by pulse width modulation so as to find the optimal current value of the preset distance, so that the time of adjusting the sensing distance of the floating button can be effectively shortened.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of a floating button trigger induction adjustment system provided by an embodiment of the present invention.

FIG. 2 is a flowchart of a floating button trigger induction adjustment method provided by an embodiment of the present invention.

FIG. 3 is a schematic diagram of a floating button trigger induction adjustment system provided by another embodiment of the present invention.

FIG. 4 is a flowchart of a floating button trigger induction adjustment method provided by another embodiment of the present invention.

### DETAILED DESCRIPTION OF PREFERRED EMBODIMENTS

The present invention is particularly described with the following examples, which are merely for illustration. For those skilled in the art, various modifications and refinements can be made without departing from the spirit and scope of this disclosure. Therefore, the scope of protection of this disclosure shall be defined by the appended claims. Throughout the specification and claims, unless clearly specified otherwise, the meaning of "a" and "the" includes "one or at least one" element or component. In addition, as used in the present invention, unless it is clearly apparent from the context that the plural is excluded, the singular also includes the plural elements or components. Additionally, when used in this description and all the following claims, unless clearly specified otherwise, "therein" can mean "in" and "on". The terms used throughout this specification and claims, unless specifically noted, usually have their ordinary meanings in the field, in the context of this disclosure, and in the specific context. Some terms used to describe the present invention will be discussed below or elsewhere in this specification to provide additional guidance to a practitioner regarding the description of the present invention. Any examples given anywhere throughout the specification, including the use of any terms discussed herein, are merely for description and do not limit the scope and meaning of the present invention or any exemplified terms. Likewise, the present invention is not limited to the various embodiments proposed in this specification.

Furthermore, if a term "coupled" or "connected" is used herein, it includes any direct and indirect electrical connection measures. For example, a text describes that a first apparatus is electrically coupled to a second apparatus, meaning that the first apparatus may be connected to the second apparatus directly or indirectly via through other apparatuses or connection measures. Additionally, if a description involves transmission or provision of electrical signals, those skilled in the art should understand that the transmission of electrical signals may be accompanied by attenuation or other non-ideal changes, but unless specifically stated otherwise, the electrical signals transmitted or provided from sources to receiving ends should be considered as substantially the same signal. For example, in a case that an electrical signal S is transmitted (or provided) from an endpoint A of an electronic circuit to an endpoint B, where it may pass by the source and drain terminals of a transistor switch and/or a possible stray capacitor, causing a voltage drop, but if the objective of such design is not to intentionally use the attenuation or other non-ideal changes during transmission (or provision) to achieve certain technical effects, the electrical signal S at the endpoint A and the electrical signal S at the endpoint B of the electronic circuit should be considered substantially the same signal.

It can be understood that the terms "comprising," "including," "having," "containing," "involving," and the like as used herein are open-ended, meaning inclusion but being not limited thereto. Additionally, any embodiment or claim of the present invention does not have to achieve all the objectives, advantages, or features disclosed in the present invention. Furthermore, the abstract and title are only for assisting in patent document searches and are not intended to limit the claims of the present invention.

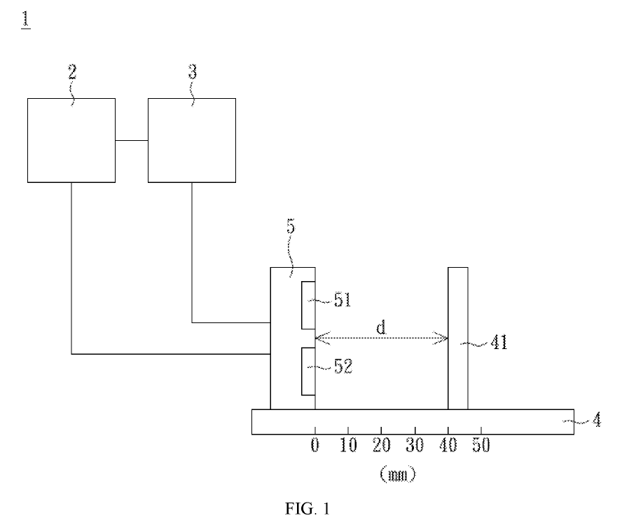

FIG. 1 is a schematic diagram of a floating button trigger induction adjustment system provided by an embodiment of the present invention. The floating button trigger induction adjustment system 1 provided by this embodiment includes a computer 2, a programming module 3, a test module 4, and a floating button circuit 5. The programming module 3 is coupled to the computer 2. The floating button circuit 5 is coupled to the computer 2 and the programming module 3 and installed on the test module 4 to sense an object 41 at a preset distance d from the floating button circuit 5 on the test module 4. It can be noted that for the common floating button circuit, the operator manually adjusts a variable resistance value of a variable resistor on the floating button circuit 5 to make a touch button sense an object within a sensing distance. For the present invention, by replacing the variable resistor with an infrared diode 51, the floating button circuit 5 automatically adjusts a current value of the infrared diode 51 in the floating button circuit 5 by pulse width modulation after the computer 2 writes a program code into the floating button circuit 5 through the programming module 3 such that the infrared diode 51 emits infrared rays to an object 41 according to an ascending current value until an infrared receiving circuit 52 of the floating button circuit 5 obtains a reflected feedback signal associated with the infrared rays. Next, the computer 2 receives a current value of the infrared diode 51 associated with the reflected feedback signal from the floating button circuit 5. Then, the computer 2 writes a program code including the current value of the infrared diode 51 associated with the reflected feedback signal into the floating button circuit 5 through the programming module 3 so as to complete the floating button trigger induction adjustment procedure. The computer 2 is capable of automatically compiling the program code to include the current value of the infrared diode 51 associated with the reflected feedback signal. In addition, the preset distance d is preferably 40mm, but those skilled in the art can design different preset distances d according to actual needs, so the present invention is not limited thereto. It should be noted that the program code written by the computer 2 through the programming module 3 may also automatically adjust the current value of the infrared diode 51 in the floating button circuit 5 according to button surface transmittances of different floating buttons, such as different light transmission areas of different numbers, and according to different preset distances d.

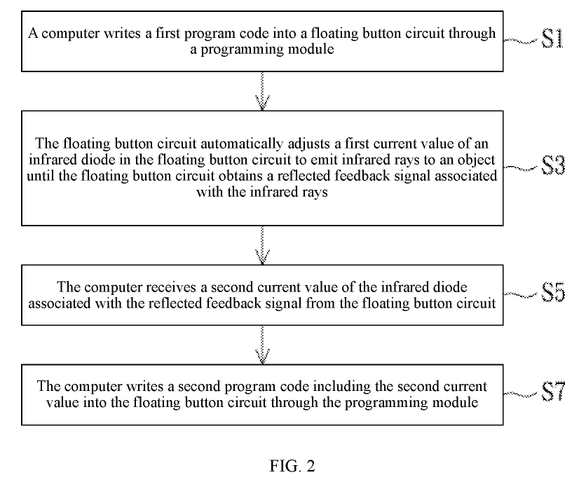

FIG. 2 is a flowchart of a floating button trigger induction adjustment method provided by an embodiment of the present invention. The floating button trigger induction adjustment method provided by this embodiment is applicable to the floating button trigger induction adjustment system 1. The floating button trigger induction adjustment method includes steps as follows. Step S1: The computer 2 writes a first program code into the floating button circuit 5 through the programming module 3. The floating button circuit 5 executes the floating button trigger induction adjustment through the first program code. Step S3: The floating button circuit 5 automatically adjusts a first current value of the infrared diode 51 in the floating button circuit 5 to emit infrared rays to the object 41 until the floating button circuit 5 obtains a reflected feedback signal associated with the infrared rays. The floating button circuit 5 emits the infrared rays to the object 41 of the test module 4 through the infrared diode 51, and the infrared receiving circuit 52 tries to receive the reflected feedback signal reflected from the object 41. While the current value of the infrared diode 51 in the floating button circuit 5 is automatically adjusted by pulse width modulation to increase gradually, the infrared receiving circuit 52 of the floating button circuit 5 receives the reflected feedback signal reflected from the object 41. Step S5: The computer 2 receives a second current value of the infrared diode 51 associated with the reflected feedback signal from the floating button circuit 5. Step S7: The computer 2 writes a second program code including the second current value into the floating button circuit 5 through the programming module 3 to complete the floating button trigger induction adjustment procedure and execute a trigger induction function of the floating button.

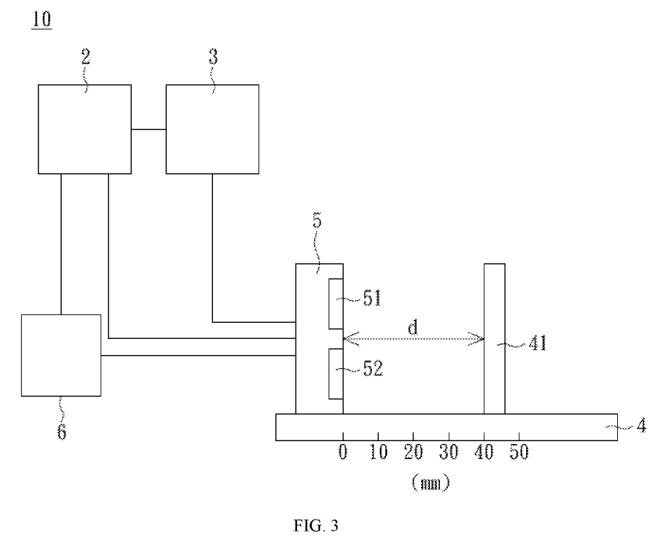

FIG. 3 is a schematic diagram of a floating button trigger induction adjustment system provided by another embodiment of the present invention. Compared with the floating button trigger induction adjustment system 1 provided by the previous embodiment, the floating button trigger induction adjustment system 10 provided by this embodiment further includes a motherboard control circuit 6 coupled to the computer 2 and the floating button circuit 5 such that the computer 2 tests an anti-false touch function of the floating button circuit 5 through the motherboard control circuit 6. For example, the computer 2 is connected to one or more floating button circuits 5 through the motherboard control circuit 6 to test the anti-false touch function of the one or more floating button circuits 5. The program code for testing the anti-false touch function of the one floating button circuit 5 may be included in the second program code so as to facilitate writing and testing and shorten the test time, or may be separate from the second program code. In addition, the computer 2, the programming module 3, the test module 4, and the floating button circuit 5 that are included in both the floating button trigger induction adjustment system 10 provided by this embodiment and the floating button trigger induction adjustment system 1 provided by the previous embodiment perform the same functions, and thus will not be repeated here.

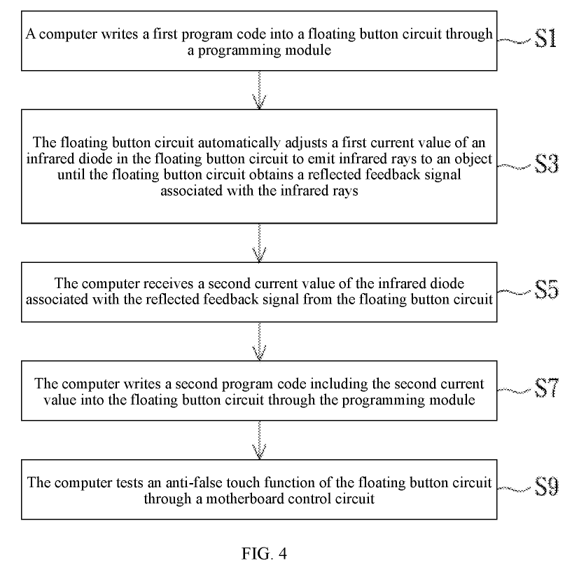

FIG. 4 is a flowchart of a floating button trigger induction adjustment method provided by another embodiment of the present invention. Compared with the floating button trigger induction adjustment method provided by the previous embodiment, the floating button trigger induction adjustment method provided by this embodiment is applicable to the floating button trigger induction adjustment system 10, and further includes step S9 after step S7: the computer 2 tests an anti-false touch function of the floating button circuit 5 through the motherboard control circuit 6. In addition, steps S1, S3, S5 and S7 that are included in both the floating button trigger induction adjustment method provided by this embodiment and the floating button trigger induction adjustment method provided by the previous embodiment are the same, and thus will not be repeated here.

Based on the above, according to the floating button trigger induction adjustment system and method in the present invention, a programming program is adopted to automatically adjust the current value of the infrared diode by pulse width modulation so as to find the optimal current value of the preset distance, so that the time of adjusting the sensing distance of the floating button can be effectively shortened.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A floating button trigger induction adjustment method, applicable to a floating button trigger induction adjustment system comprising a computer, a programming module, a test module, and a floating button circuit, the programming module being coupled to the computer, the floating button circuit being coupled to the computer and the programming module, the floating button circuit being installed on the test module to sense an object at a preset distance, and the floating button trigger induction adjustment method comprising:
writing, by the computer, a first program code into the floating button circuit through the programming module;
automatically adjusting, by the floating button circuit, a first current value of an infrared diode in the floating button circuit to emit infrared rays to the object until the floating button circuit obtains a reflected feedback signal associated with the infrared rays;
receiving, by the computer, a second current value of the infrared diode associated with the reflected feedback signal from the floating button circuit; and
writing, by the computer, a second program code comprising the second current value into the floating button circuit through the programming module.

2. The floating button trigger induction adjustment method according to claim 1, wherein the floating button trigger induction adjustment system further comprises a motherboard control circuit coupled to the computer and the floating button circuit, and the floating button trigger induction adjustment method further comprises:
testing, by the computer, an anti-false touch function of the floating button circuit through the motherboard control circuit.

3. The floating button trigger induction adjustment method according to claim 1, wherein the computer automatically compiles the second program code to comprise the second current value.

4. The floating button trigger induction adjustment method according to claim 1, wherein the preset distance is 40 mm.

5. The floating button trigger induction adjustment method according to claim 1, wherein the floating button circuit automatically adjusts the first current value of the infrared diode in the floating button circuit by pulse width modulation.

6. A floating button trigger induction adjustment system, comprising:
a computer;
a programming module, coupled to the computer;
a test module; and
a floating button circuit, coupled to the computer and the programming module, and installed on the test module to sense an object at a preset distance;
wherein a floating button trigger induction adjustment method is executed by the floating button trigger induction adjustment system to comprise:
writing, by the computer, a first program code into the floating button circuit through the programming module;
automatically adjusting, by the floating button circuit, a first current value of an infrared diode in the floating button circuit to emit infrared rays to the object until the floating button circuit obtains a reflected feedback signal associated with the infrared rays;
receiving, by the computer, a second current value of the infrared diode associated with the reflected feedback signal from the floating button circuit; and
writing, by the computer, a second program code comprising the second current value into the floating button circuit through the programming module.

7. The floating button trigger induction adjustment system according to claim 6, wherein the floating button trigger induction adjustment system further comprises a motherboard control circuit coupled to the computer and the floating button circuit, and the floating button trigger induction adjustment method further comprises:
testing, by the computer, an anti-false touch function of the floating button circuit through the motherboard control circuit.

8. The floating button trigger induction adjustment system according to claim 6, wherein the computer automatically compiles the second program code to comprise the second current value.

9. The floating button trigger induction adjustment system according to claim 6, wherein the preset distance is 40 mm.

10. The floating button trigger induction adjustment system according to claim 6, wherein the floating button circuit automatically adjusts the first current value of the infrared diode in the floating button circuit by pulse width modulation.
